(19) United States
(12) Patent Application Publication
(10) Pub. No.: US 2024/0014299 A1
(43) Pub. Date: Jan. 11, 2024

(54) SEMICONDUCTOR DEVICE

(71) Applicant: ROHM CO., LTD., Kyoto-shi (JP)

(72) Inventor: Kohei MURASAKI, Kyoto-shi (JP)

(73) Assignee: ROHM CO., LTD., Kyoto-shi (JP)

(21) Appl. No.: 18/470,433

(22) Filed: Sep. 20, 2023

Related U.S. Application Data
(63) Continuation of application No. PCT/JP2022/007066, filed on Feb. 22, 2022.

(30) Foreign Application Priority Data
Mar. 23, 2021 (JP) 2021-048986

(51) Int. Cl. H01L 29/739; H01L 29/06; H01L 29/417; H01L 29/78

(52) U.S. Cl. CPC H01L 29/7397; H01L 29/0696; H01L 29/41708; H01L 29/7813

(57) ABSTRACT

This semiconductor device comprises a peripheral region surrounding a cell region, a gate electrode disposed in the peripheral region, and an emitter electrode. The emitter electrode includes a cell electrode portion, a peripheral electrode portion formed at a distance from the cell electrode portion in the peripheral region, and a connecting portion connecting the cell electrode portion and the peripheral electrode portion. The peripheral region includes a well region formed to surround the cell region, an insulating film and an intermediate insulating film that cover the well region, and a gate finger embedded in the insulating films. The connecting portion is formed across the gate finger on the intermediate insulating film. The peripheral electrode portion is electrically connected to the well region.

### CROSS-REFERENCE TO RELATED APPLICATIONS

This application is a continuation of International Application No. PCT/JP2022/007066, filed Feb. 22, 2022, which claims priority to JP 2021-048986, filed Mar. 23, 2021, the entire contents of each are incorporated herein by reference.

### BACKGROUND

### 1. Field

The present disclosure relates to a semiconductor device.

### 2. Description of Related Art

In a semiconductor device such as an insulated gate bipolar transistor (IGBT) used in, for example, a vehicle inverter device, an emitter extension formed integrally with an emitter electrode surrounds a gate finger in order to reduce heat generation (refer to, for example, Japanese Laid-Open Patent Publication No. 2018-120990).

### BRIEF DESCRIPTION OF THE DRAWINGS

FIG. 1 is a plan view illustrating a semiconductor device of a first embodiment.

FIG. 2 is an enlarged view illustrating a gate electrode and its surroundings in the semiconductor device of FIG. 1.

FIG. 3 is a cross-sectional view illustrating the cross-sectional structure of a cell region in the semiconductor device of FIG. 1.

FIG. 4 is a cross-sectional view illustrating the cross-sectional structure of a peripheral region in the semiconductor device of FIG. 1.

FIG. 5 is a cross-sectional view illustrating the cross-sectional structure of the semiconductor device taken along line 5-5 in FIG. 1.

FIG. 6 is a cross-sectional view illustrating the cross-sectional structure of the semiconductor device taken along line 6-6 in FIG. 1.

FIG. 7 is a plan view illustrating a semiconductor device of a comparative example.

FIG. 8 is a cross-sectional view illustrating the cross-sectional structure of the semiconductor device of the comparative example taken along line 8-8 in FIG. 7.

FIG. 9 is a cross-sectional view illustrating the cross-sectional structure of the semiconductor device of the comparative example taken along line 9-9 in FIG. 7.

FIG. 10 is a plan view illustrating a semiconductor device of a second embodiment.

FIG. 11 is an enlarged view illustrating a gate electrode and its surroundings in the semiconductor device of FIG. 10.

FIG. 12 is a cross-sectional view illustrating the cross-sectional structure of the semiconductor device taken along line 12-12 in FIG. 10.

FIG. 13 is a cross-sectional view illustrating the cross-sectional structure of the semiconductor device taken along line 13-13 in FIG. 10.

FIG. 14 is an enlarged plan view illustrating a gate electrode and its surroundings in a semiconductor device of a modified example.

### DETAILED DESCRIPTION

Embodiments of a semiconductor device will now be described with reference to the drawings. The embodiments described below exemplify configurations and methods for embodying a technical concept without any intention to limit the material, shape, structure, arrangement, dimensions, and the like of each component.

### First Embodiment

### Structure of Semiconductor Device

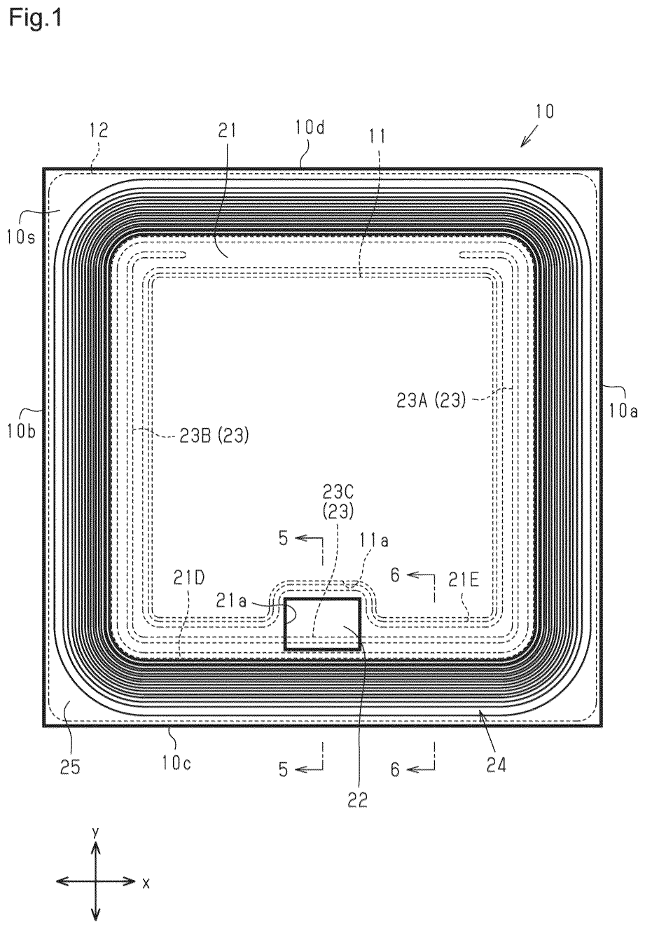

A semiconductor device 10 of one embodiment will now be described with reference to FIGS. 1 to 6.

As shown in FIG. 1, a semiconductor device 10 of the present embodiment is a trench-gate type insulated gate bipolar transistor (IGBT). The semiconductor device 10 is used as, for example, a switching element in an inverter device for a vehicle. In this case, a current in, for example, the range of 5 A to 1000 A flows through the semiconductor device 10.

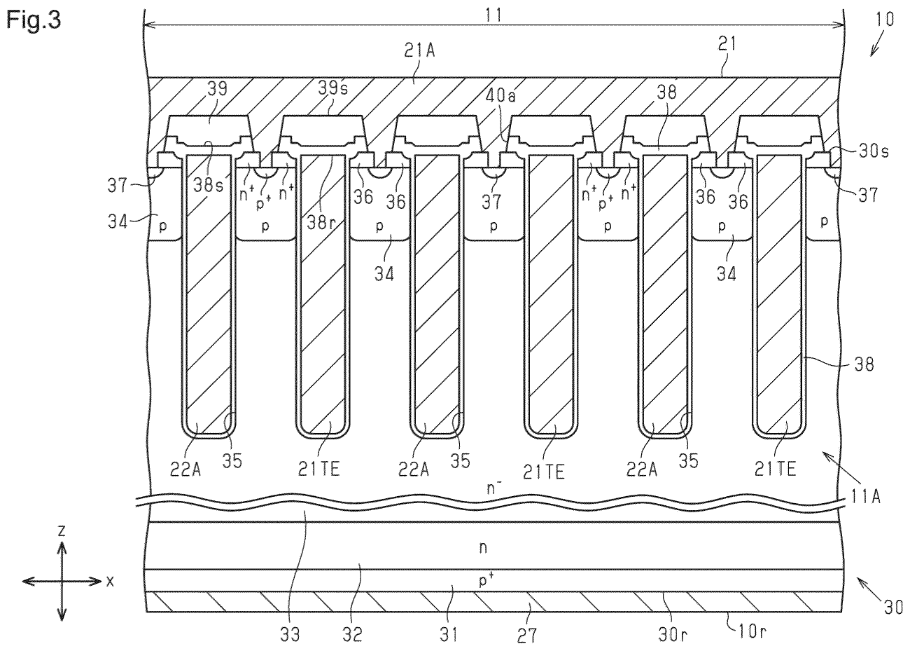

As shown in FIG. 1, the semiconductor device 10 has the form of, for example, a rectangular plate. In the present embodiment, the semiconductor device 10 includes a device main surface 10s that has, for example, the form of a square. In the present embodiment, each side of the device main surface 10s has a length of approximately 11 mm. That is, the semiconductor device 10 of the present embodiment has a chip size of 11 mm×11 mm. The semiconductor device 10 includes a device back surface 10r (refer to FIG. 3), which faces a direction opposite the device main surface 10s, and four device side surfaces 10a to 10d, which are formed between the device main surface 10s and the device back surface 10r. The device side surfaces 10a to 10d, for example, connect the device main surface 10s to the device back surface 10r and are orthogonal to both of the device main surface 10s and the device back surface 10r.

In the description hereafter, the direction that the device main surface 10s and the device back surface 10r face are referred to as the z-direction, and the z-direction may also be referred to as the height direction of the semiconductor device 10. Two directions that are orthogonal to each other and orthogonal to the z-direction are referred to as the x-direction and the y-direction. In the present embodiment, the device side surfaces 10a and 10b define the two end surfaces of the semiconductor device 10 in the x-direction, and the device side surfaces 10c and 10d define the two end surfaces of the semiconductor device 10 in the y-direction. For the sake of simplicity, the direction extending from the device back surface 10r toward the device main surface 10s will be referred to as the upward direction, and the direction extending from the device main surface 10s toward the device back surface 10r will be referred to as the downward direction. A view of the semiconductor device 10 taken in the z-direction will be referred to as a plan view.

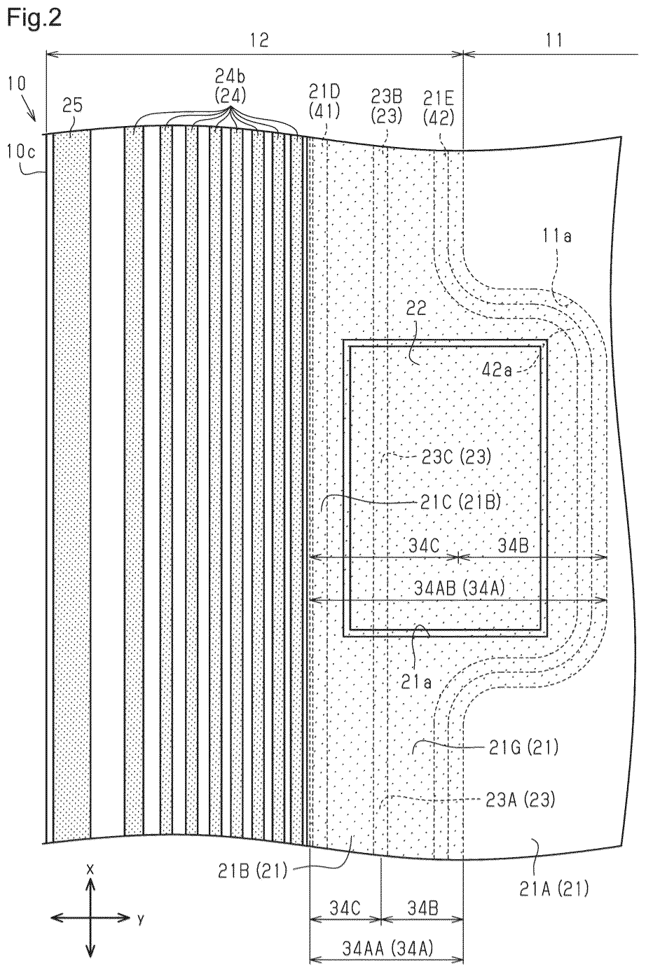

As shown in FIG. 2, the semiconductor device 10 includes an emitter electrode 21, a gate electrode 22, and a collector electrode 27 (refer to FIG. 3) that serve as external electrodes used to connect the semiconductor device 10 to an external device.

The emitter electrode 21 forms the emitter of the IGBT and is the electrode through which the main current of the semiconductor device 10 flows. The emitter electrode 21 is formed on the device main surface 10s. An open portion 21a is formed in the emitter electrode 21 at a portion that is in the middle part in the x-direction and is located closer to the device side surface 10c than the central part in the y-direction.

The gate electrode 22 forms the gate of the IGBT and is provided with a drive voltage signal from outside the semiconductor device 10 to drive the semiconductor device 10. The gate electrode 22 is formed on the device main surface 10s. The gate electrode 22 is formed in the open portion 21a of the emitter electrode 21.

The collector electrode 27 forms the collector of the IGBT and is the electrode through which the main current of the semiconductor device 10 flows. More specifically, in the semiconductor device 10, the main current flows from the collector electrode 27 toward the emitter electrode 21. The collector electrode 27 is formed on the device back surface 10r. More specifically, the collector electrode 27 is formed over the entire device back surface 10r.

As shown by the broken lines in FIGS. 1 and 2, the semiconductor device 10 includes a cell region 11, in which cells 11A (refer to FIG. 3) are formed, and a peripheral region 12, which is located at the outer side of the cell region 11 surrounding the cell region 11. The cells 11A refer to main cells that form the transistor. Thus, the cell region 11 is where the transistor is formed. In the present embodiment, the cell region 11 is shaped to be rectangular in plan view.

The emitter electrode 21 is arranged in the cell region 11. The emitter electrode 21 is formed over most of the cell region 11. The emitter electrode 21 is shaped in conformance with the cell region 11 in plan view. The cells 11A are not formed in the cell region 11 where the gate electrode 22 is formed. More specifically, the cell region 11 includes a recess 11a that is curved to avoid the gate electrode 22.

The peripheral region 12 is where a terminal end structure is arranged to increase the dielectric breakdown voltage of the semiconductor device 10. The peripheral region 12 is a looped region defined by the peripheral portion of the device main surface 10s in plan view. The peripheral region 12 is a region in the device main surface 10s other than the cell region 11 in plan view.

The gate electrode 22 and part of the emitter electrode 21 are arranged in the peripheral region 12. The peripheral region 12 includes a gate finger 23, a field limiting ring (FLR) 24, and an equipotential ring 25. The emitter electrode 21, the gate electrode 22, field plates 24b (eight field plates in present embodiment) of the FLR 24, and the equipotential ring 25 share a common metal film. The metal film is formed from, for example, material containing AlCu (alloy of aluminum and copper).

The gate finger 23 is configured so that the current supplied to the gate electrode 22 also flows to the cells 11A at the part of the emitter electrode 21 separated from the gate electrode 22. The gate finger 23 is connected to the gate electrode 22.

The gate finger 23 is arranged in the peripheral portion of the emitter electrode 21. The gate finger 23 surrounds the cell region 11. The gate finger 23 is formed by a metal interconnection. The gate finger 23 overlaps the peripheral portion of the emitter electrode 21 in plan view. In the present embodiment, the gate finger 23 is formed by a material containing tungsten (W).

The gate finger 23 includes gate fingers 23A, 23B, and 23C. The gate finger 23A extends from the gate electrode 22 toward the device side surface 10a and surrounds the cell region 11 from the device side surface 10c, the device side surface 10a, and the device side surface 10d. The gate finger 23B extends from the gate electrode 22 toward the device side surface 10b and surrounds the cell region 11 from the device side surface 10c, the device side surface 10b, and the device side surface 10d. The distal end of the gate finger 23A and the distal end of the gate finger 23B face each other spaced apart by a gap in the x-direction at a part located toward the device side surface 10d from the emitter electrode 21. The gate finger 23C overlaps the gate electrode 22 in plan view. The gate finger 23C connects the gate finger 23A and the gate finger 23B. There may be more than one gate finger 23.

The FLR 24 is located outward from the emitter electrode 21 and forms a terminal end structure that increases the breakdown voltage of the semiconductor device 10. The FLR 24 is looped and surrounds the emitter electrode 21 and the gate electrode 22. In the present embodiment, the FLR 24 forms a closed loop. The FLR 24 weakens the electric field in the peripheral region 12 and limits the effect of external ions to increase the breakdown voltage of the semiconductor device 10.

The equipotential ring 25 is looped and surrounds the FLR 24 to form a terminal end structure that increases the breakdown voltage of the semiconductor device 10. In the present embodiment, the equipotential ring 25 forms a closed loop. The equipotential ring 25 has the functionality for increasing the breakdown voltage of the semiconductor device 10.

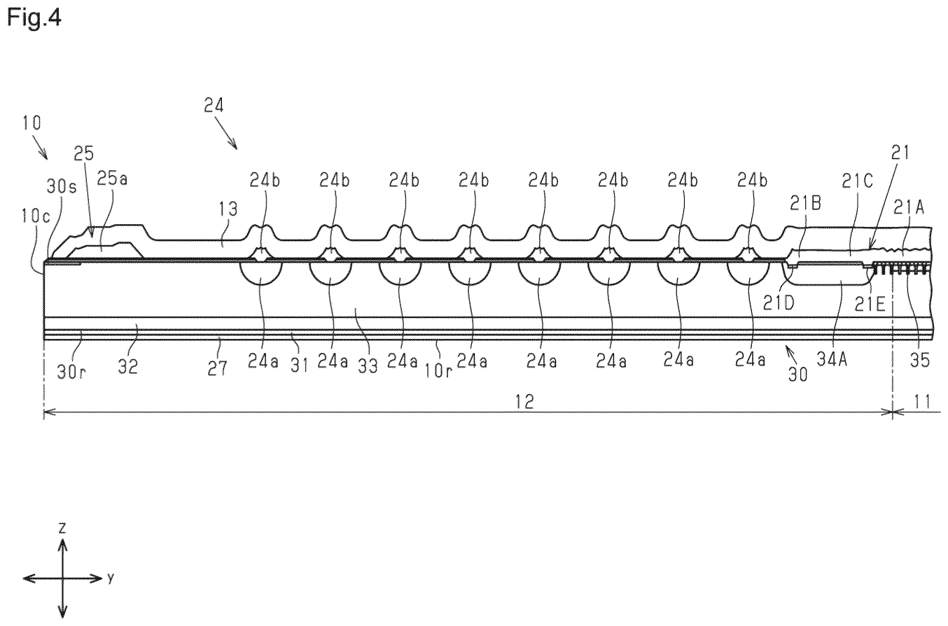

The semiconductor device 10 includes a passivation film 13 (refer to FIG. 4) covering both of the cell region 11 and the peripheral region 12. The passivation film 13 covers the emitter electrode 21, the gate electrode 22, the FLR 24, and the equipotential ring 25. The passivation film 13 is a protective film protecting the semiconductor device 10 from outside the semiconductor device 10. The passivation film 13 is, for example, an organic insulation film formed from a material containing polyimide (PI). FIGS. 1 and 2 do not show the passivation film 13 to aid understanding.

The passivation film 13 includes a first open portion (not shown) that exposes part of the emitter electrode 21 and a second open portion (not shown) that exposes most of the gate electrode 22. The part of the emitter electrode 21 exposed from the first open portion defines an emitter electrode pad. The part of the gate electrode 22 exposed from the second open portion defines a gate electrode pad.

FIG. 3 shows one example of the cross-sectional structure of part of the cell region 11. FIG. 3 shows some of the elements of the semiconductor device 10 in the cell region 11 without hatching lines for the sake of simplicity.

As shown in FIG. 3, the semiconductor device 10 includes a semiconductor substrate 30. The semiconductor substrate 30 is formed from a material containing, for example, an n⁻ type silicon (Si). The semiconductor substrate 30 has a thickness in, for example, a range of 50 μm to 200 μm.

The semiconductor substrate 30 includes a substrate head surface 30s and a substrate back surface 30r at opposite sides in the z-direction. Thus, the z-direction is also the depth direction of the semiconductor substrate 30.

The semiconductor substrate 30 includes a stack of a p⁺-type collector layer 31, an n-type buffer layer 32, and an n⁻-type drift layer 33 arranged in order from the substrate back surface 30r toward the substrate head surface 30s. The collector electrode 27 is formed on the substrate back surface 30r. The collector electrode 27 is formed over substantially the entire substrate back surface 30r. The surface of the collector electrode 27 at the side opposite the side where the substrate back surface 30r is located defines the device back surface 10r of the semiconductor device 10.

The p-type dopant of the collector layer 31 is, for example, boron (B), aluminum (Al), or the like. The collector layer 31 has an impurity concentration in, for example, a range of 1×10¹⁵ cm⁻³ to 2×10¹⁹ cm⁻³.

The n-type dopant of the buffer layer 32 and the drift layer 33 is, for example, nitride (N), phosphorus (P), arsenic (As), or the like. The buffer layer 32 has an impurity concentration in, for example, a range of 1×10¹⁵ cm⁻³ to 5×10¹⁷ cm⁻³. The drift layer 33 has an impurity concentration that is lower than that of the buffer layer 32 and is in, for example, a range of 1×10¹³ cm⁻³ to 5×10¹⁴ cm⁻³.

The head surface of the drift layer 33, that is, the substrate head surface 30s includes a p-type base region 34. The base region 34 is formed over substantially the entire substrate head surface 30s. The base region 34 has an impurity concentration in, for example, a range of 1×10¹⁶ cm⁻³ to 1×10¹⁸ cm⁻³. The base region 34 has a depth from the substrate head surface 30s that is in, for example, a range of 1.0 μm to 4.0 μm.

The head surface of the base region 34 (substrate head surface 30s) in the cell region 11 includes trenches 35 arranged next to one another. The trenches 35, for example, each extend in the y-direction and are separated from one another in the x-direction. This defines strips of the cells 11A. The intervals between adjacent ones of the trenches 35 in the x-direction (distance between centers of trenches 35) is in, for example, a range of 1.5 μm to 7.0 μm. Each trench 35 has a width (dimension of trench 35 in x-direction) that is in, for example, a range of 0.5 μm to 3.0 μm. Each trench 35 extends through the base region 34 in the z-direction to an intermediate part of the drift layer 33. The trenches 35 may be formed in a lattice pattern to define a grid of the cells 11A.

The head surface of the base region 34 in the cell region 11 (substrate head surface includes n⁺-type emitter regions 36. The emitter regions 36 are located at opposite sides of each trench 35 in the x-direction. That is, the emitter regions 36 are located in the base region 34 at opposite sides of each trench 35 in the arrangement direction of the trenches 35. Two emitter regions 36 are arranged between adjacent ones of the trenches 35 in the x-direction and are spaced apart from each other in the x-direction. Each emitter region 36 has a depth that is in, for example, a range of 0.2 μm to 0.6 μm. The emitter regions 36 have an impurity concentration that is greater than that of the base region 34 and is in, for example, a range of 1×10¹⁹ cm⁻³ to 5×10²⁰ cm⁻³.

The head surface of the base region 34 in the cell region 11 (substrate head surface includes p⁺-type base contact regions 37. The base contact regions 37 are located adjacent to the emitter regions 36 in the x-direction. That is, each base contact region 37 is located between two emitter regions 36 in the x-direction that are located between adjacent ones of the trenches 35 in the x-direction. The base contact regions 37 may be formed deeper than the emitter regions 36. Each base contact region 37 has a depth that is in, for example, a range of 0.2 μm to 0.8 μm. Each base contact region 37 has an impurity concentration that is higher than that of the base region 34 and is in, for example, a range of 5×10¹⁸ cm⁻³ to 1×10²⁰ cm⁻³.

An insulation film 38 is formed integrally on both of the wall surface of each trench and the substrate head surface 30s. This means that the insulation film 38 is formed on the head surface of the drift layer 33. The insulation film 38 contains, for example, silicon oxide (SiO₂). The insulation film 38 has a thickness that is, for example, in a range of 1100 angstroms to 1300 angstroms. The insulation film 38 in the cell region 11 forms a gate insulation film. The insulation film 38 formed on the substrate head surface 30s has a back surface 38r facing the same direction as the substrate back surface 30r. In the present embodiment, the back surface 38r of the insulation film 38 is in contact with the substrate head surface 30s.

An electrode material of, for example, polysilicon or the like is embedded in each trench 35 under the insulation film 38. The electrode material embedded in each trench 35 is electrically connected to either one of the gate electrode 22 (gate finger 23) or the emitter electrode 21. Thus, the trenches 35 define gate trenches 22A and emitter trenches 21TE when embedded with the electrode material. In the present embodiment, the gate trenches 22A and the emitter trenches 21TE are arranged alternately in the arrangement direction of the trenches 35. In the present embodiment, the gate trenches 22A and the emitter trenches 21TE are both embedded with the electrode material to the open ends of the corresponding trenches 35.

An intermediate insulation film 39 is formed on a head surface 38S of the insulation film 38, which is arranged on the substrate head surface 30s. The intermediate insulation film 39 contains, for example, SiO₂. The thickness of the intermediate insulation film 39, which is greater than that of the insulation film 38, is in a range of 3000 angstroms to 15000 angstroms.

The emitter electrode 21 is formed on a head surface 39s of the intermediate insulation film 39. The intermediate insulation film 39 is an interlayer insulation film filling the space between the emitter electrode 21 and the gate trenches 22A and the space between the emitter electrode 21 and the emitter trenches 21TE.

Contact holes 40a exposing the base contact regions 37 are formed in the cell region 11 extending through both of the intermediate insulation film 39 and the insulation film 38. The emitter electrode 21 is partially embedded in the contact holes 40a to contact the base contact regions 37.

FIG. 4 shows an example of the cross-sectional structure of part of the peripheral region 12.

As shown in FIG. 4, the peripheral region 12 includes a well region 34A that is a semiconductor region of a second conductive type (p-type in present embodiment). The well region 34A is formed in the head surface of the drift layer 33 (substrate head surface 30s of semiconductor substrate 30). The well region 34A has a depth that is greater than that of the base region 34. In the present embodiment, the depth of the well region 34A is greater than that of the trenches 35. The well region 34A has an impurity concentration that is greater than the impurity concentration of the drift layer 33 and lower than the impurity concentration of the base region 34. In one example, the impurity concentration of the well region 34A is in a range of 1×10¹⁶ cm⁻³ to 1×10¹⁸ cm⁻³.

The FLR 24 is located outward from the well region 34A. The FLR 24 includes multiple (four in present embodiment) looped conductors, which are separated from one another, and semiconductor regions.

Multiple (eight in present embodiment) looped guard rings 24a are formed in the substrate head surface 30s of the semiconductor substrate 30. In the present embodiment, each guard ring 24a has the form of a closed loop. Part of each guard ring 24a is formed in the drift layer 33. The guard rings 24a are semiconductor regions of the second conductive type (p-type in present embodiment) and separated from one another in a direction orthogonal to the z-direction. In the present embodiment, the guard rings 24a each have a depth that is the same as the depth of the well region 34A. The p-type dopant of the guard rings 24a is, for example, boron (B), aluminum (Al), or the like. The guard rings 24a each have an impurity concentration that is, for example, the same as the impurity concentration of the well region 34A and is in, for example, the range of 1×10¹⁶ cm⁻³ to 1×10¹⁸ cm⁻³. In this case, the guard rings 24a and the well region 34A may be formed in the same process.

The FLR 24 includes the field plates 24b that are arranged in correspondence with the guard rings 24a. The field plates 24b are each arranged on the intermediate insulation film 39. The field plates 24b overlap the corresponding guard rings 24a in plan view.

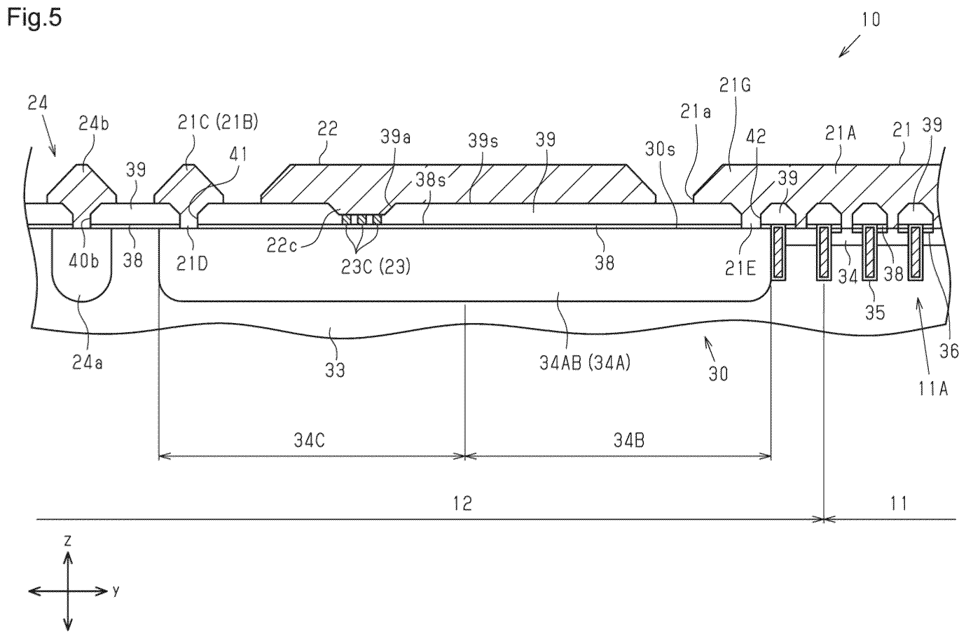

The field plates 24b contact the corresponding guard rings 24a. More specifically, open portions 40b (refer to FIG. 5) are formed in the intermediate insulation film 39 and the insulation film 38 at positions corresponding to the guard rings 24a to expose the guard rings 24a. The field plates 24b contact the corresponding guard rings 24a through the corresponding open portions 40b. In the present embodiment, each of the guard rings 24a and each of the field plates 24b is in an electrically floating state.

The equipotential ring 25 includes a channel stop region (not shown) of a first conductive type (n⁺-type) formed on the head surface of the drift layer 33 (substrate head surface 30s), an internal interconnection (not shown) formed in the insulation film 38 and the intermediate insulation film 39, and a head surface interconnection 25a arranged on the intermediate insulation film 39.

The channel stop region extends from a position where the head surface interconnection 25a is located to the device side surface 10c as viewed in the z-direction. The channel stop region is located outward from the internal interconnection (toward device side surface 10c). The channel stop region has an impurity concentration that is, for example, the same as the impurity concentration of the emitter regions 36 (refer to FIG. 3), and is in the range of 1×10¹⁹ cm⁻³ to 5×10²⁰ cm⁻³. In this case, for example, the channel stop region is formed in the same process as the emitter regions 36.

The internal interconnection is arranged on the insulation film 38 and covered by the intermediate insulation film 39. The internal interconnection is formed from an electrode material of polysilicon or the like. An oxide film is formed on the head surface of the internal interconnection.

The head surface interconnection 25a overlaps both of the channel stop region and the internal interconnection in plan view. The head surface interconnection 25a is formed from, for example, a material containing AlCu. The head surface interconnection 25a is electrically connected to both of the channel stop region and the internal interconnection. More specifically, a first open portion is formed in the intermediate insulation film 39 and the insulation film 38 at a position corresponding to the channel stop region. The head surface interconnection 25a includes a first contact that contacts the channel stop region through the first open portion. The intermediate insulation film 39 includes a second open portion at a position corresponding to the internal interconnection. The head surface interconnection 25a includes a second contact that contacts the internal interconnection through the second open portion.

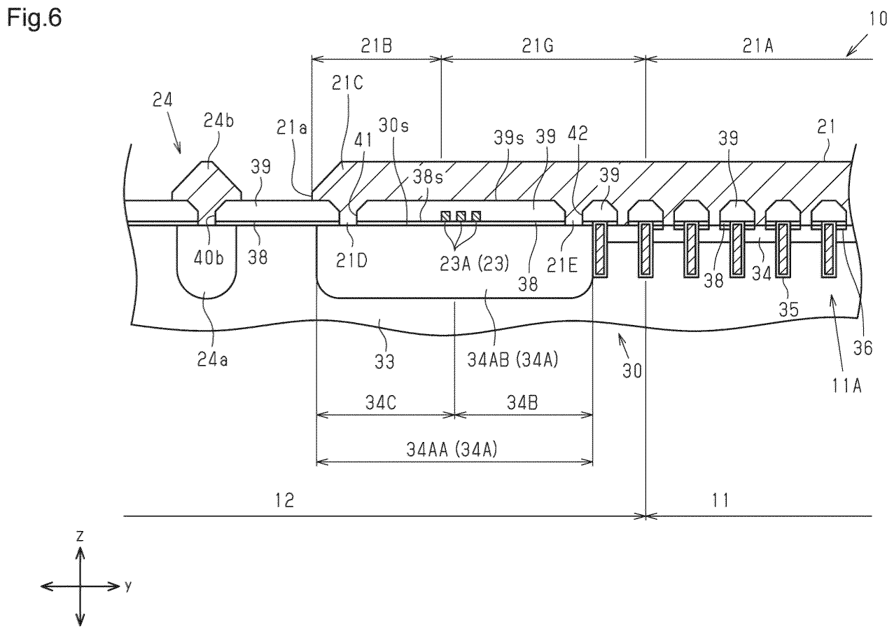

FIGS. 5 and 6 show one example of the cross-sectional structure of part of the cell region 11 and part of the peripheral region 12. FIGS. 5 and 6 show some of the elements of the semiconductor device 10 in the cell region 11 and the peripheral region 12 without hatching lines for the sake of simplicity. Further, FIGS. 5 and 6 do not show the passivation film 13 for the sake of simplicity.

As shown in FIGS. 2, 5, and 6, in the present embodiment, the well region 34A is adjacent to the cell region 11. The well region 34A surrounds the cell region 11 in plan view. The well region 34A has the form of a loop with a width in a direction orthogonal to the z-direction (e.g., x-direction or y-direction) in plan view. As shown in FIG. 5, the well region 34A is formed overlapping the gate electrode 22. The gate electrode 22 is arranged in the well region 34A in plan view.

The well region 34A around the cell region 11 includes a first well region 34AA having a first width and a second well region 34AB having a second width. The second well region 34AB extends into the recess 11a of the cell region 11. The second well region 34AB is rectangular in plan view. The second well region 34AB overlaps the gate electrode 22 in plan view.

The first well region 34AA is connected to the two ends of the second well region 34AB in the x-direction and has the form of a loop surrounding the cell region 11. The first well region 34AA is connected to the one of the two ends of the second well region 34AB in the y-direction that is farther from a cell electrode portion 21A of the emitter electrode 21, which will be described later. In other words, the second well region 34AB is located inward from the FLR 24 and adjacent to the FLR 24.

The well region 34A includes an inner portion 34B that is closer than its widthwise direction center to the cell electrode portion 21A, and a peripheral portion 34C that is farther from the widthwise direction center than the cell electrode portion 21A. The peripheral portion 34C is closer to the peripheral region 12 than the widthwise direction center.

The insulation film 38 is formed on the substrate head surface 30s in the peripheral region 12. The intermediate insulation film 39 is formed on the insulation film 38, which is formed on the substrate head surface 30s. Thus, the insulation film 38 and the intermediate insulation film 39 are both formed in the cell region 11 and the peripheral region 12.

The gate electrode 22 is formed on the head surface 39s of the intermediate insulation film 39. The intermediate insulation film 39 is an interlayer insulation film filling the space between the gate electrode 22 and the well region 34A. Further, the intermediate insulation film 39 is an interlayer insulation film filling the space between the field plates 24b and the guard rings 24a of the FLR 24 (refer to FIG. 4).

In the present embodiment, the intermediate insulation film 39 and the insulation film 38 correspond to an insulation film. The head surface 39s of the intermediate insulation film 39 corresponds to a head surface of the insulation film, and the back surface 38r of the insulation film 38 corresponds to a back surface of the insulation film.

Structures of Emitter Electrode, Gate Electrode, and Gate Finger

With reference to FIGS. 2, 5, and 6, the structures of the emitter electrode 21, the gate electrode 22, and the gate finger 23A (23B) will now be described. The gate finger 23B has the same structure as the gate finger 23A and thus will not be described.

The emitter electrode 21 overlaps both of the cell region 11 and the peripheral region 12 in plan view. The emitter electrode 21 is located inward from the looped FLR 24.

The emitter electrode 21 includes the cell electrode portion 21A arranged in the cell region 11, a peripheral electrode portion 21B formed in the peripheral region 12 distanced from the cell electrode portion 21A, and a connecting portion 21G connecting the cell electrode portion 21A and the peripheral electrode portion 21B. In the present embodiment, the cell electrode portion 21A, the peripheral electrode portion 21B, and the connecting portion 21G are formed integrally.

The cell electrode portion 21A covers the entire cell region 11 in plan view. Thus, the cell electrode portion 21A is shaped to be rectangular in plan view. In the present embodiment, the cell electrode portion 21A corresponds to an electrode portion.

The peripheral electrode portion 21B covers the inner part of the peripheral region 12. The inner part of the peripheral region 12 is the part of the peripheral region 12 located inward from the FLR 24. The peripheral electrode portion 21B is located outward from the gate finger 23. Thus, the peripheral electrode portion 21B covers the inner part of the peripheral region 12 that is close to the FLR 24. Further, the peripheral electrode portion 21B is formed in a manner avoiding the gate electrode 22. In this manner, the peripheral electrode portion 21B is the part of the peripheral region 12 distanced from the cell region 11 in plan view.

The peripheral electrode portion 21B covers the part of the well region 34A that does not overlap the gate electrode 22 and is located outward from the gate finger 23. More specifically, the peripheral electrode portion 21B covers the part of the peripheral portion 34C of the second well region 34AB that is located outward from the gate electrode 22. The peripheral electrode portion 21B covers the part of the peripheral portion 34C of the first well region 34AA located outward from the gate fingers 23A and 23B.

In the present embodiment, the peripheral electrode portion 21B is looped and surrounds the cell electrode portion 21A in plan view. The peripheral electrode portion 21B is the peripheral part of the emitter electrode 21.

As described above, the emitter electrode 21 includes the open portion 21a in which the gate electrode 22 is arranged. The peripheral electrode portion 21B and the connecting portion 21G both include a part located adjacent to the open portion 21a of the emitter electrode 21 in the x-direction, that is, a part located adjacent to the gate electrode 22 in the emitter electrode 21 in the x-direction. In the present embodiment, as shown in FIG. 2, the open portion 21a is formed over the peripheral electrode portion 21B and the connecting portion 21G in the x-direction.

As shown in FIGS. 5 and 6, the peripheral electrode portion 21B includes a peripheral end 21C located outward from the gate electrode 22 in the y-direction. The peripheral end 21C of the peripheral electrode portion 21B, which has the form of a loop with a width, is the one of the two widthwise ends of the peripheral electrode portion 21B that is closer to the FLR 24. The peripheral end 21C includes a part located between the gate electrode 22 and the FLR 24 in the y-direction.

The connecting portion 21G is located between the cell electrode portion 21A and the peripheral electrode portion 21B. The connecting portion 21G is located in the peripheral region 12 and covers the gate fingers 23A and 23B in plan view. Thus, the connecting portion 21G covers the inner part of the peripheral region 12. The connecting portion 21G covers the entire periphery of the cell electrode portion 21A in plan view. The connecting portion 21G has the form of a loop with a width.

The connecting portion 21G covers the part of the well region 34A located inward from the gate finger 23 in plan view and does not cover the part of the well region 34A overlapping the gate electrode 22. More specifically, the connecting portion 21G covers the part of the inner portion 34B of the second well region 34AB that is located inward from the gate electrode 22. Further, the connecting portion 21G partially covers the inner portion 34B and the peripheral portion 34C of the first well region 34AA. The connecting portion 21G covers the part of the peripheral portion 34C of the first well region 34AA that overlaps the gate fingers 23A and 23B in plan view. In this manner, the emitter electrode 21 covers the entire well region 34A with the peripheral electrode portion 21B and the connecting portion 21G. The peripheral electrode portion 21B includes the connecting portion 21G. The gate fingers 23A and 23B overlap the peripheral electrode portion 21B in plan view.

The insulation film 38 and the intermediate insulation film 39 extend over both of the cell region 11 and the peripheral region 12. Thus, the insulation film 38 and the intermediate insulation film 39 cover the well region 34A.

The insulation film 38 and the intermediate insulation film 39 both include a first open portion 41 and a second open portion 42 that extend through the insulation film 38 and the intermediate insulation film 39. The open portions 41 and 42 expose the well region 34A from the insulation film 38 and the intermediate insulation film 39. Thus, the first open portion 41 and the second open portion 42 both overlap the well region 34A in plan view.

The first open portion 41 and the cell electrode portion 21A are located at opposite sides of the gate finger 23. In other words, the first open portion 41 is located farther from the cell electrode portion 21A than the gate finger 23. The first open portion 41 extends in the x-direction overlapping the peripheral end 21C. Thus, the first open portion 41 and the cell electrode portion 21A are located at opposite sides of the gate electrode 22 in the y-direction.

The first open portion 41 overlaps the peripheral portion 34C of the well region 34A in plan view. In the present embodiment, the first open portion 41 overlaps the peripheral end of the well region 34A. The peripheral end of the well region 34A is the one of the two ends of the well region 34A that is closer to the FLR 24 in the widthwise direction of the well region 34A.

The second open portion 42 is located closer to the cell electrode portion 21A than the gate finger 23. As shown in FIG. 2, the second open portion 42 includes a recess 42a and is shaped in conformance with the open portion 21a of the emitter electrode 21 in plan view. Thus, the second open portion 42 extending in the y-direction overlaps the gate electrode 22 as viewed in the x-direction and bends to avoid the gate electrode 22 in plan view.

The second open portion 42 overlaps the inner portion 34B of the well region 34A in plan view. In the present embodiment, the second open portion 42 overlaps the inner end of the well region 34A. The inner end of the well region 34A is the one of the two ends of the well region 34A in the widthwise direction of the well region 34A that is closer to the emitter electrode 21.

The peripheral electrode portion 21B covers the first open portion 41 in plan view. The peripheral electrode portion 21B includes a first contact 21D embedded in the first open portion 41. Thus, the first contact 21D is shaped in conformance with the first open portion 41 in plan view.

The connecting portion 21G covers the second open portion 42 in plan view. The connecting portion 21G includes a second contact 21E embedded in the second open portion 42. Thus, the second contact 21E is shaped in conformance with the second open portion 42 in plan view.

The first contact 21D is in contact with the peripheral portion 34C of the well region 34A. This electrically connects the peripheral electrode portion 21B to the well region 34A. In the present embodiment, the first contact 21D is in contact with the peripheral end of the well region 34A. Thus, the peripheral electrode portion 21B is electrically connected to the well region 34A at the peripheral end of the well region 34A. The first contact 21D is looped at the peripheral end 21C of the peripheral electrode portion 21B in plan view. Thus, the first contact 21D includes a part located at a side of the gate electrode 22 that is opposite to the cell electrode portion 21A.

The second contact 21E contacts the inner portion 34B of the well region 34A. Thus, the connecting portion 21G is electrically connected to the well region 34A. The second contact 21E is looped at the inner end of the connecting portion 21G in plan view. The inner end of the connecting portion 21G is the part of the cell electrode portion 21A, which has the form of a loop with a width, in the widthwise direction located toward the connecting portion 21G. Thus, the second contact 21E is a part located closer to the cell electrode portion 21A than the gate electrode 22. In the present embodiment, the second contact 21E is in contact with the inner end of the well region 34A. Thus, the connecting portion 21G is electrically connected to the well region 34A at the inner end of the well region 34A.

The gate finger 23 is embedded in the insulation film including the insulation film 38 and the intermediate insulation film 39. In the present embodiment, the gate finger 23 is formed on the head surface 38s of the insulation film 38 and covered by the intermediate insulation film 39.

As shown in FIGS. 2 and 6, the gate fingers 23A and 23B (not shown in FIG. 6) overlap the connecting portion 21G in plan view. The gate fingers 23A and 23B overlap the well region 34A in plan view. The gate fingers 23A and 23B are located between the first contact 21D and the second contact 21E in plan view. In the present embodiment, the gate fingers 23A and 23B are arranged near the central part of the first well region 34AA in the widthwise direction of the well region 34A. In one example, as shown in FIG. 6, one of the gate fingers 23A overlaps the peripheral portion 34C of the first well region 34AA in plan view, and another one of the gate fingers 23A overlaps the inner portion 34B of the first well region 34AA in plan view. The remaining one of the gate fingers 23A overlaps the boundary between the inner portion 34B and the peripheral portion 34C of the first well region 34AA in plan view. The gate fingers 23B are positioned relative to the first well region 34AA in the same manner as the gate fingers 23A.

As shown in FIG. 5, the gate fingers 23C overlap the one of the two ends of the gate electrode 22 in the y-direction that is closer to the peripheral end (end closer to FLR 24) in plan view. Thus, the gate fingers 23C are located closer to the first contact 21D than the second contact 21E. Further, the gate fingers 23C overlap the peripheral portion 34C of the second well region 34AB in plan view. In the present embodiment, the gate fingers 23C extend in the x-direction.

The intermediate insulation film 39 corresponding to the gate fingers 23C includes an open portion 39a that exposes the gate fingers 23A. The open portion 39a is not formed in the intermediate insulation film 39 that corresponds to the gate fingers 23A and 23B. The gate electrode 22 includes an embedded electrode portion 22c in the open portion 39a. The embedded electrode portion 22c is in contact with the gate fingers 23C. This electrically connects the gate electrode 22 and the gate finger 23.

Method for Manufacturing Semiconductor Device 10

A method for manufacturing the semiconductor device 10 of the present embodiment will now be described.

The method for manufacturing the semiconductor device 10 includes the steps of preparing the semiconductor substrate 30 including the n⁻-type the drift layer 33, forming the p-type well region 34A and the guard rings 24a on the semiconductor substrate 30, forming the trenches 35, forming the insulation film 38, embedding polysilicon as the electrode material in each trench, and forming the emitter trenches 21TE and the gate trenches 22A. These steps are performed in a known manner.

The method for manufacturing the semiconductor device 10 includes the step of forming the gate finger 23. For example, a metal interconnection of a material containing tungsten (W) is formed on the head surface 38s of the insulation film 38 to form the gate finger 23.

The method for manufacturing the semiconductor device 10 includes the steps of forming the intermediate insulation film 39, forming the open portions 41 and 42 in both of the intermediate insulation film 39 and the insulation film 38, and forming the open portion 39a in the intermediate insulation film 39. The intermediate insulation film 39 is first formed on the exposed head surface 38s of the insulation film 38. In this case, the intermediate insulation film 39 is formed to cover the gate finger 23. Then, the open portion 39a, the first open portion 41, and the second open portion 42 are formed in both of the intermediate insulation film 39 and the insulation film 38. Afterwards, the open portion 39a is formed in the region of the intermediate insulation film 39 where the gate electrode 22 is formed. This exposes the gate finger 23C through the open portion 39a.

The method for manufacturing the semiconductor device 10 includes the step of forming the emitter electrode 21, the gate electrode 22, the field plates 24b of the FLR 24, and the equipotential ring 25. This step is performed in a known manner. In this case, the first contact 21D, the second contact 21E, and the embedded electrode portion 22c are formed.

The method for manufacturing the semiconductor device 10 includes the step of forming the buffer layer 32, the collector layer 31, and the collector electrode 27. More specifically, n-type and p-type dopants are selectively ion-implanted and dispersed in the substrate back surface 30r of the semiconductor substrate 30 to sequentially form the buffer layer 32 and the collector layer 31. Then, the collector electrode 27 is formed on the surface of the collector layer 31 at the side opposite the buffer layer 32. The semiconductor device 10 is manufactured through the steps described above.

Operation of First Embodiment

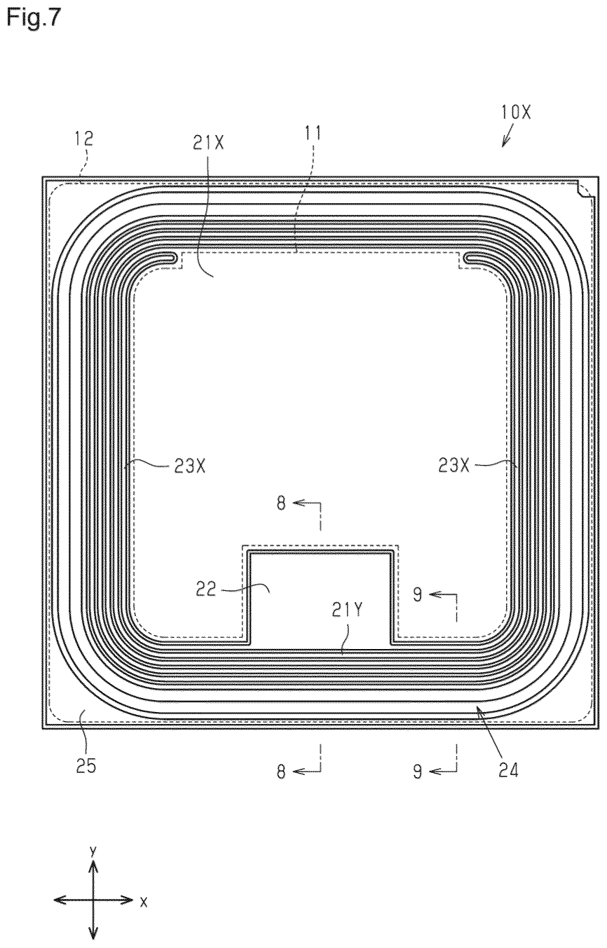

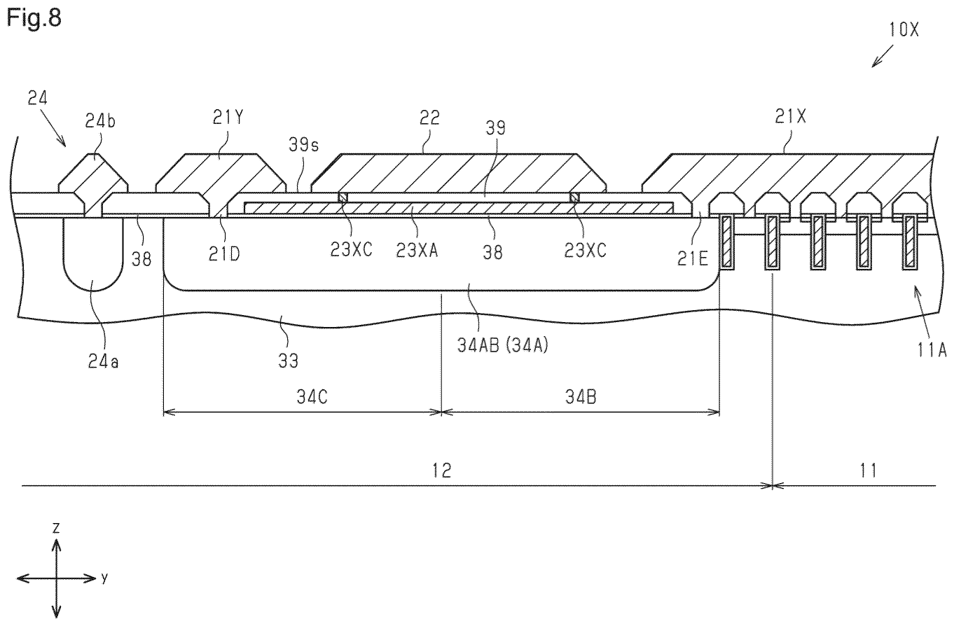

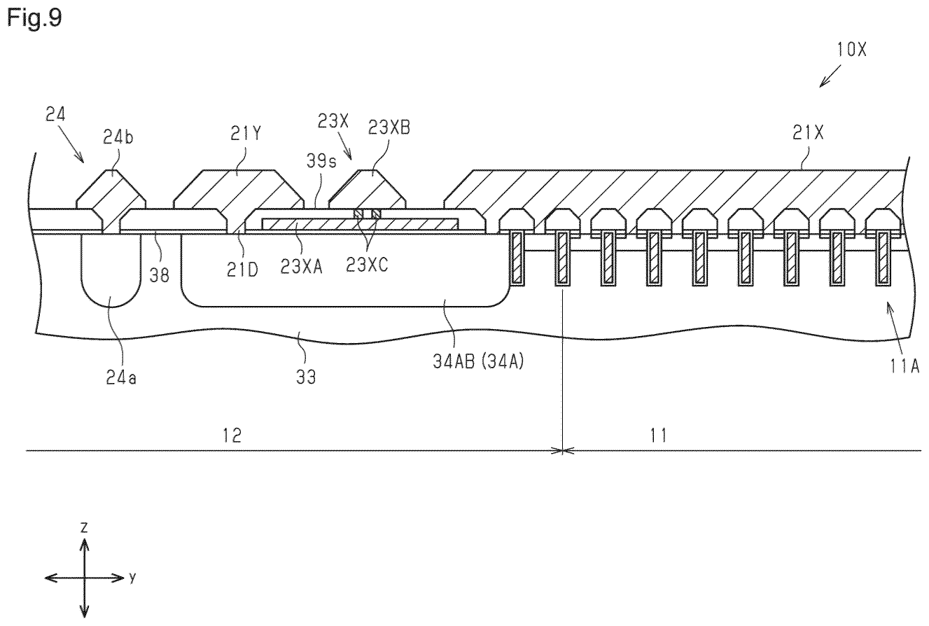

The operation of the semiconductor device 10 of the present embodiment will now be described. FIG. 7 is a plan view illustrating a semiconductor device 10X of a comparative example, FIG. 8 is a cross-sectional view illustrating the semiconductor device 10X of the comparative example taken along line 8-8 in FIG. 7, and FIG. 9 is a cross-sectional view illustrating the semiconductor device 10X of the comparative example taken along line 9-9 in FIG. 7.

As shown in FIGS. 7 to 9, the semiconductor device 10X of the comparative example includes an emitter electrode 21X that has an emitter extension 21Y. The emitter extension 21Y is a looped interconnection extending from the one of the two ends of the emitter electrode 21X in the y-direction that is closer to the device side surface 10d so as to surround the emitter electrode 21X. The emitter extension 21Y is integrated with the emitter electrode 21X. The emitter extension 21Y is located outward from the gate electrode 22 and a gate finger 23X. Thus, the gate electrode 22 and the gate finger 23X are both located between the emitter electrode 21X and the emitter extension 21Y.

As shown in FIG. 9, the gate finger 23X includes an internal interconnection 23XA embedded in the intermediate insulation film 39, an external interconnection 23XB formed on the intermediate insulation film 39, and a connecting interconnection 23XC connecting the internal interconnection 23XA and the external interconnection 23XB. Thus, the external interconnection 23XB cannot be positioned to overlap the emitter electrode 21X, and is thus located outward from the emitter electrode 21X in plan view. The external interconnection 23XB of the gate finger 23X is integrated with the gate electrode 22. Further, as shown in FIG. 8, the internal interconnection 23XA and the connecting interconnection 23XC, which are arranged in the intermediate insulation film 39, extend in a manner overlapping the gate electrode 22 in the intermediate insulation film 39.

As shown in FIG. 9, the external interconnection 23XB of the gate finger 23X is located between the emitter extension 21Y and the emitter electrode 21X. Thus, the emitter electrode 21X includes an open space to allow for the arrangement of the external interconnection 23XB. That is, the emitter electrode 21X is formed avoiding the external interconnection 23XB. Thus, the external interconnection 23XB of the gate finger 23X hinders enlargement of the emitter electrode 21X.

In the present embodiment, as shown in FIGS. 5 and 6, the first contact 21D, which is located in the peripheral electrode portion 21B of the emitter electrode 21, is in contact with the peripheral portion 34C of the well region 34A. Thus, the first contact 21D corresponds to the emitter extension 21Y. Further, the gate finger 23 is embedded in the intermediate insulation film 39 and the insulation film 38, and the connecting portion 21G is formed covering the gate finger 23. Thus, the emitter electrode 21 is formed overlapping the gate finger 23 in plan view. Consequently, the emitter electrode 21 does not have to avoid the gate finger 23. This allows the emitter electrode 21 to be larger in size than the emitter electrode 21X.

Advantages of First Embodiment

The semiconductor device 10 of the present embodiment has the advantages described below.

(1-1) The semiconductor device 10 includes the cell region 11, the gate electrode 22 located in a region that differs from the cell region 11, the peripheral region 12 surrounding the cell region 11 and the gate electrode 22, and the emitter electrode 21 that includes the peripheral electrode portion 21B, which is formed in the peripheral region 12 and is distanced from the cell electrode portion 21A, and the connecting portion 21G, which connects the cell electrode portion 21A and the peripheral electrode portion 21B. The peripheral region 12 includes the well region 34A surrounding the cell region 11, the insulation film 38 and the intermediate insulation film 39 that cover the well region 34A, and the gate finger 23 embedded in the insulation film formed by the insulation film 38 and the intermediate insulation film 39. The gate finger 23, which is connected to the gate electrode 22, surrounds the cell region 11. The peripheral electrode portion 21B of the emitter electrode 21 is electrically connected to the well region 34A through the first open portion 41, which is formed in the intermediate insulation film 39 and the insulation film 38 at the side of the gate finger 23 opposite the cell electrode portion 21A.

With this configuration, the connecting portion 21G covers the gate finger 23. This allows the emitter electrode 21 to be enlarged in size. That is, the area of the emitter electrode 21 can be enlarged in plan view. This allows more heat to be dissipated from the emitter electrode 21.

(1-2) The well region 34A, which has the form of a loop with a width, includes the peripheral portion 34C that is farther from the cell electrode portion 21A than the widthwise direction center of the well region 34A. The peripheral electrode portion 21B includes the first contact 21D that is in contact with the well region 34A. The first contact 21D is in contact with the peripheral portion 34C of the well region 34A in plan view.

With this configuration, current flowing from the collector electrode 27 to the emitter electrode 21 flows via the peripheral portion 34C of the well region 34A and the first contact 21D to the cell electrode portion 21A. Thus, the amount of the current flowing from the collector electrode 27 to the emitter electrode 21 is reduced where the current flows through the peripheral portion 34C and the inner portion 34B of the well region 34A to the cell electrode portion 21A. In other words, the path of the current flowing from the collector electrode 27 to the emitter electrode 21 is shortened in the well region 34A. This reduces the heat generated by the current flowing to the well region 34A.

(1-3) The first contact 21D includes a part located at a side of the gate electrode 22 that is opposite to the cell electrode portion 21A.

With this configuration, the peripheral electrode portion 21B includes a part located at the side of the gate electrode 22 opposite the cell electrode portion 21A. This allows the emitter electrode 21 to be enlarged in area.

(1-4) The second open portion 42 is formed in the insulation film 38 and the intermediate insulation film 39 closer to the cell electrode portion 21A than the gate finger 23 in plan view. The peripheral electrode portion 21B includes the second contact 21E that is in contact with the well region 34A through the second open portion 42.

With this configuration, the first contact 21D and the second contact 21E increases the paths of current flowing from the collector electrode 27 to the emitter electrode 21. This allows the current flowing from the collector electrode 27 to the emitter electrode 21 to be increased in amount.

(1-5) The gate finger 23 is formed by a metal interconnection.

With this configuration, the gate finger 23 has a lower resistance than when the gate finger 23 is formed from, for example, polysilicon. This allows current to be readily supplied via the gate finger 23 to the cells 11A.

(1-6) The gate finger 23 is separated from both of the back surface 38r of the insulation film 38 and the head surface 39s of the intermediate insulation film 39.

With this configuration, the gate finger 23 will neither be electrically connected to the semiconductor substrate 30 nor the emitter electrode 21.

(1-7) The gate finger 23 is formed on the head surface 38s of the insulation film 38 and covered by the intermediate insulation film 39.

With this configuration, the gate finger 23 is embedded in the insulation film formed by the insulation film 38 and the intermediate insulation film 39. Thus, an open portion does not have to be formed in the intermediate insulation film 39. This simplifies the process for embedding the gate finger 23 in the insulation film formed by the insulation film 38 and the intermediate insulation film 39.

### Second Embodiment

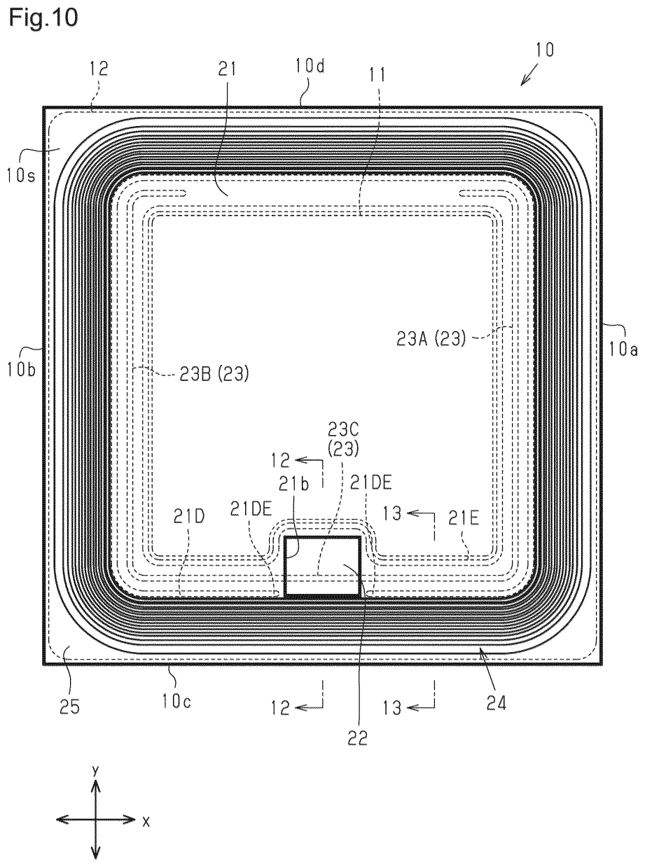

With reference to FIGS. 10 to 13, the semiconductor device 10 of a second embodiment will now be described. The semiconductor device 10 of the present embodiment differs from the semiconductor device 10 of the first embodiment in the structure of the emitter electrode 21. The description hereafter will focus on the differences from the semiconductor device 10 of the first embodiment. Same reference numerals are given to those components that are the same as the corresponding components in the semiconductor device 10 of the first embodiment. Such components will not be described in detail.

As shown in FIG. 10, the emitter electrode 21 includes a recess 21b instead of the open portion 21a. The recess 21b is arranged in the one of the two ends of the emitter electrode 21 in the y-direction that is closer the device side surface 10c at the central part in the x-direction. The recess 21b is open toward the device side surface 10c. The gate electrode 22 is arranged in the recess 21b. In this manner, in the present embodiment, the emitter electrode 21 has no part arranged between the gate electrode 22 and the FLR 24 in the y-direction.

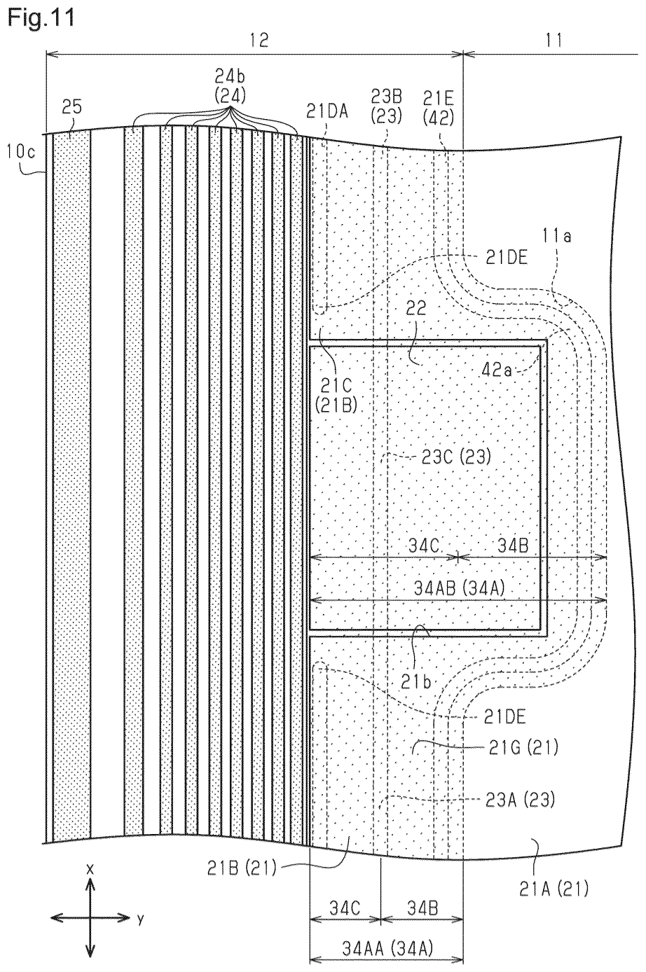

As shown in FIG. 11, the gate electrode 22 overlaps one of two ends of the emitter electrode 21 in the y-direction that is closer to the device side surface 10c. More specifically, the one of the two ends of the gate electrode 22 in the y-direction that is closer to the device side surface 10c and the one of the two ends of the emitter electrode 21 in the y-direction that is closer to the device side surface 10c are aligned with each other in the y-direction and separated from each other in the x-direction. Thus, the gate electrode 22 overlaps the peripheral end 21C of the peripheral electrode portion 21B in the emitter electrode 21.

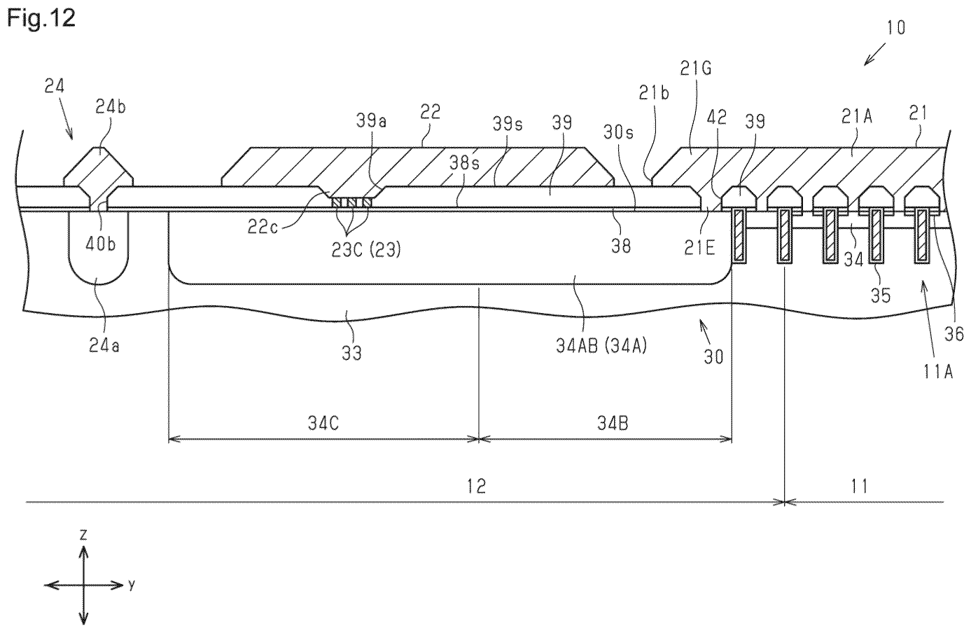

As shown in FIGS. 11 and 12, the first contact 21D of the peripheral electrode portion 21B is not formed where the gate electrode 22 is arranged. The first contact 21D includes two ends 21DE in the direction in which the first contact 21D extends that are adjacent to the gate electrode 22 in the x-direction. Thus, the first contact 21D has the form of an open loop extending along the peripheral end 21C of the peripheral electrode portion 21B except for a part where the gate electrode 22 is arranged.

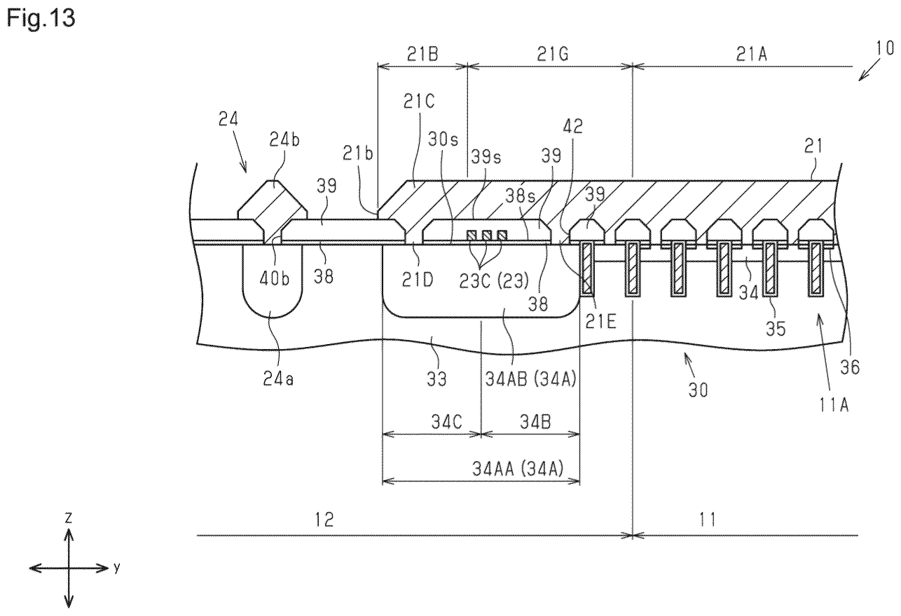

In this manner, the first contact 21D includes a contact portion 21DA, which is located toward the device side surface 10c and extends in the x-direction, and is located closer to the cell electrode portion 21A in the y-direction than the first contact 21D of the first embodiment. Thus, as shown in FIG. 13, the distance between the first contact 21D and the second contact 21E is shorter than the distance between the first contact 21D and the second contact 21E in the first embodiment. As a result, as shown in FIGS. 12 and 13, in the well region 34A, the width of the first well region 34AA and the width of the second well region 34AB are both decreased.

Operation of Second Embodiment

In the semiconductor device 10 of the comparative example shown in FIGS. 7 to 9, the emitter extension 21Y is located between the gate electrode 22 and the FLR 24. This hinders reduction in the chip size of the semiconductor device 10X of the comparative example.

In addition, with reference to FIGS. 8 and 9, the emitter extension 21Y is in contact with the well region 34A. Thus, the emitter extension 21Y increases the width of the well region 34A. As a result, when current flows from the collector electrode 27 via the well region 34A to the second contact 21E of the emitter electrode 21X, the path of the current flowing through the well region 34A is increased in length. The well region 34A has a higher resistance than the emitter electrode 21X, consequently making the well region 34A susceptible to heating due to the current flow.

In the present embodiment, as shown in FIG. 11, the one of the two ends of the emitter electrode 21 in the y-direction that is closer to the device side surface 10c is aligned with the one of the two ends of the gate electrode 22 in the y-direction that is closer to the device side surface 10c. In other words, the emitter electrode 21 has no part arranged between the gate electrode 22 and the FLR 24 in the y-direction This allows the semiconductor device 10 to have a smaller chip size than the semiconductor device 10X of the comparative example.

Further, in the present embodiment, as shown in FIGS. 12 and 13, the width of the well region 34A decreases as the distance decreases between the first contact 21D and the second contact 21E in the y-direction. As a result, when current flows from the collector electrode 27 (refer to FIG. 2) via the well region 34A to the second contact 21E of the emitter electrode 21, the path of the current flowing through the well region 34A is decreased in length. This reduces the amount of heat generated by the current flowing through the well region 34A.

Advantages of Second Embodiment

In addition to advantages (1-1), (1-2), and (1-4) to (1-7), the semiconductor device 10 of the present embodiment has the advantage described below.

(2-1) The gate electrode 22 overlaps the peripheral end 21C of the peripheral electrode portion 21B in the emitter electrode 21. The first contact 21D has the form of an open loop extending along the peripheral end 21C of the peripheral electrode portion 21B except for the part where the gate electrode 22 is arranged.

With this configuration, the peripheral electrode portion 21B is not located outward from the gate electrode 22. That is, the first contact 21D is not located outward from the gate electrode 22. This allows the peripheral region 12 to be decreased in area in plan view. Thus, the semiconductor device 10 can be reduced in size.

### Modified Examples

The embodiments described above exemplify, without any intention to limit, applicable forms of a semiconductor device according to this disclosure. The semiconductor device in accordance with this disclosure may be modified from the embodiments described above. For example, the configuration in each of the above embodiments may be replaced, changed, or omitted in part or include an additional element. The modified examples described below may be combined as long as there is no technical contradiction. In the modified examples described hereafter, same reference characters are given to those components that are the same as the corresponding components of the above embodiments. Such components will not be described in detail.

In the first embodiment, the first contact 21D and the second contact 21E may have any shape. In one example, the first contact 21D may have the form of a loop that is partially cut to be open. The second contact 21E may have the form of a loop that is partially cut to be open.

In each of the above embodiments, the peripheral electrode portion 21B of the emitter electrode 21 may have any shape. In one example, the peripheral electrode portion 21B may have the form of a loop with the peripheral part of the cell electrode portion 21A being partially cut to be open.

In each of the above embodiments, the connecting portion 21G of the emitter electrode 21 may have any shape. In one example, the connecting portion 21G may have the form of a loop with the peripheral part of the cell electrode portion 21A being partially cut to be open.

In each of the above embodiments, the gate fingers 23C may be located at any position relative to the gate electrode 22 in plan view. In one example, the gate fingers 23C may be located at the central part of the gate electrode 22 in the y-direction in plan view.

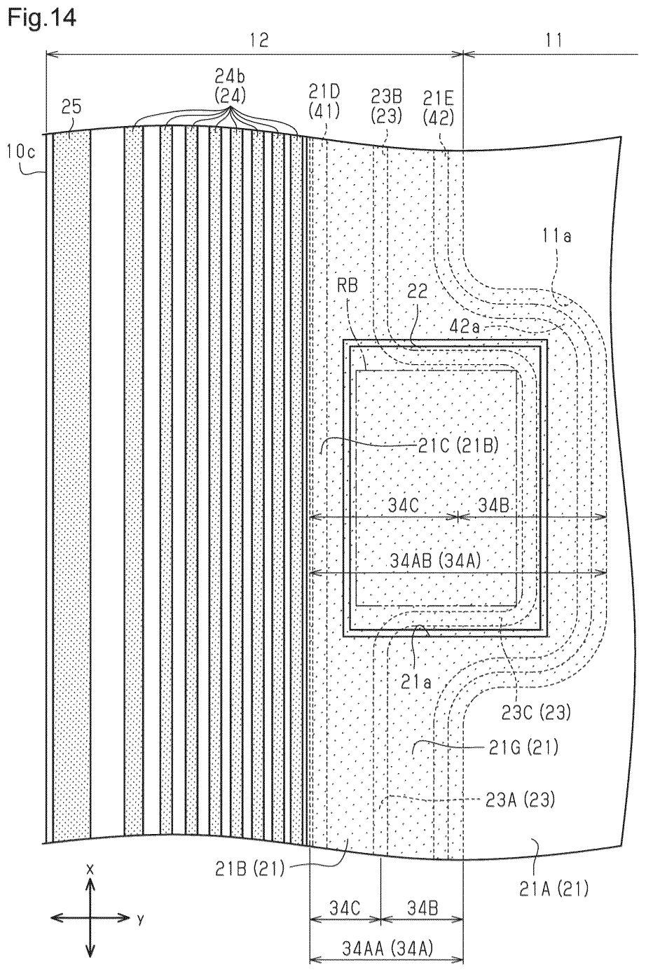

In each of the above embodiments, the gate fingers 23C may have any shape in plan view. In one example, as shown in FIG. 14, the gate fingers 23C may be formed to avoid a region RB in the gate electrode 22 where a conductive member, such as a wire, is joined with the gate electrode 22.

In each of the above embodiments, a further insulation film may be formed on the head surface 39s of the intermediate insulation film 39. In this case, the head surface of the further insulation film will correspond to a head surface of the insulation film. One example of the further insulation film is, for example, a barrier layer formed by material containing silicon nitride. The barrier layer limits the entry of external ions into the intermediate insulation film 39 and the insulation film 38 and thereby limits electrical charging of the intermediate insulation film 39 and the insulation film 38 that would be caused by external ions. In this case, the emitter electrode 21, the gate electrode 22, and the field plates 24b of the FLR 24 are formed in the head surface of the barrier layer.

In each of the above embodiments, the first contact 21D may be separate from the peripheral electrode portion 21B. Further, the second contact 21E may be separate from the connecting portion 21G. In this case, the first contact 21D and the second contact 21E may be formed from, for example, a material containing tungsten (W).

In each of the above embodiments, the quantity of the first contact 21D and the quantity of the second contact 21E may each be changed. In one example, there may be more than one first contact 21D. In this case, the first contacts 21D may be separated from each other in the widthwise direction of the peripheral electrode portion 21B.

In each of the above embodiments, the second contact 21E may be omitted from the connecting portion 21G.

In each of the above embodiments, the gate electrode 22 may be located at any position relative to the emitter electrode 21. In one example, the gate electrode 22 may be arranged at one of the four corners of the emitter electrode 21.

In each of the above embodiments, the quantity of the gate finger 23 may be changed. For example, there may be one, two, or at least four gate fingers 23.

In each of the above embodiments, the configuration in which the gate finger 23 is embedded in the insulation film 38 and the intermediate insulation film 39 may be changed. In one example, the gate finger 23 may be embedded in the intermediate insulation film 39. That is, the gate finger 23 may be separated from the head surface 38s of the insulation film 38.

In each of the above embodiments, the gate finger 23 may have any shape in plan view. In one example, the gate finger 23 may be looped to surround the cell region 11 in plan view.

In each of the above embodiments, at least one of the FLR 24 and the equipotential ring 25 may be omitted.

In each of the above embodiments, the emitter trenches 21TE and the gate trenches 22A are arranged alternately. This, however, is not a limitation and the emitter trenches 21TE and the gate trenches 22A may be in any arrangement.

In each of the above embodiments, the semiconductor device 10 may be a planar gate IGBT instead of a trench gate IGBT.

In each of the above embodiments, the semiconductor device 10 is embodied as an IGBT. Instead, the semiconductor device 10 may be a trench type SiC metal-oxide-semiconductor field-effect transistor (MOSFET) or a Si-MOSFET. In this case, the source electrode of the MOSFET will correspond to a drive electrode.

In this specification, the word “on” includes the meaning of “above” in addition to the meaning of “on” unless otherwise described in the context. Accordingly, the phrase of “A formed on B” means that A contacts B and is directly arranged on B, and may also mean, as a modified example, that A is arranged above B without contacting B. Thus, the word “on” will also allow for a structure in which another member is formed between A and B.

The z-direction referred to in this specification does not necessarily have to be the vertical direction and does not necessarily have to fully coincide with the vertical direction. Accordingly, in the structures of the present disclosure, up and down in the z-direction as referred to in this specification is not limited to up and down in the vertical direction. For example, the x-direction may be the vertical direction. Alternatively, the y-direction may be the vertical direction.

### CLAUSES

Technical concepts that can be understood from the above embodiment and the modified examples will now be described. The reference characters used to denote elements of the embodiments are shown in parenthesis for the corresponding elements of the clauses described below. The reference characters are given as examples to aid understanding and not intended to limit elements to the elements denoted by the reference characters.

### [Clause 1]

A semiconductor device (10), including:
a cell region (11) in which cells (11A) are arranged;
a peripheral region (12) surrounding the cell region (11);
a gate electrode (22) located in the peripheral region (12); and
a drive electrode (21) including an electrode portion (21A) arranged in the cell region (11), a peripheral electrode portion (21B) formed in the peripheral region (12) and distanced from the electrode portion (21A), and a connecting portion (21G) connecting the electrode portion (21A) and the peripheral electrode portion (21B), where:
the peripheral region (12) includes
   a well region (34A) that is a semiconductor region arranged surrounding the cell region (11),
   an insulation film (38, 39) covering the well region (34A) and arranged surrounding the cell region (11) in plan view, and
   a gate finger (23) embedded in the insulation film (38, 39), connected to the gate electrode (22), and formed surrounding the cell region (11);
the connecting portion (21G) is formed on the insulation film (38, 39) so as to extend across the gate finger (23); and
the peripheral electrode portion (21B) is electrically connected to the well region (34A).

### [Clause 2]

The semiconductor device according to clause 1, where:
the well region (34A) has the form of a loop with a width and includes a peripheral portion (34C) that is farther from the electrode portion (21A) than a widthwise direction center of the well region (34A); and
the contact (21D) is in contact with the peripheral portion (34C) of the well region (34A) as viewed in a thickness direction (z-direction) of the insulation film (38, 39).

### [Clause 3]

The semiconductor device according to clause 1 or 2, where the contact (21D) includes a part located at a side of the gate electrode (22) opposite the electrode portion (21A).

[Clause 4]

The semiconductor device according to clause 3, where the contact (21D) has the form of a loop at a peripheral end (21C) of the peripheral electrode (21B) as viewed in a thickness direction (z-direction) of the insulation film (38, 39).

### [Clause 5]

The semiconductor device according to clause 1 or 2, where:
the gate electrode (22) is arranged overlapping a peripheral end (21C) of the peripheral electrode portion (21B); and
the contact (21D) has the form of an open loop extending along the peripheral end (21C) of the peripheral electrode (21B) except for a part where the gate electrode (22) is arranged.

### [Clause 6]

The semiconductor device according to any one of clauses 1 to 5, where:
the open portion is a first open portion (41);
a second open portion (42) is formed in the insulation film (38, 39) located closer to the electrode portion (21A) than the gate finger (23) as viewed in a thickness direction (z-direction) of the insulation film (38, 39);
the contact is a first contact (21D); and
the connecting portion (21G) includes a second contact (21E) that is in contact with the well region (34A) through the second open portion (42).

### [Clause 7]

The semiconductor device according to any one of clauses 1 to 6, where the gate finger (23) is formed by a metal interconnection.

### [Clause 8]

The semiconductor device according to clause 7, where the gate finger (23) is formed by a material containing tungsten.

### [Clause 9]

The semiconductor device according to any one of clauses 1 to 8, where the gate finger (23) is one of a multiple gate fingers arranged in the insulation film (38, 39) and spaced apart from each other in a direction orthogonal to a thickness direction (z-direction) of the insulation film (38, 39).

### [Clause 10]

The semiconductor device according to any one of clauses 1 to 9, where:
the insulation film (38, 39) includes a head surface (39s) and a back surface (38r) at opposite sides in a thickness direction (z-direction) of the insulation film (38, 39); and
the gate finger (23) is arranged spaced apart from both of the head surface (39s) and the back surface (38r) in the thickness direction (z-direction) of the insulation film (38, 39).

### [Clause 11]

The semiconductor device according to clause 10, where:
the insulation film (38, 39) includes
   a first insulation film (38) that covers the well region (34A) and includes the back surface (38r), and
   a second insulation film (39) that is formed on the first insulation film (38) and includes the head surface (39s); and
the gate finger (23) is formed on the first insulation film (38) and covered by the second insulation film (39).

### [Clause 12]

The semiconductor device according to clause 10 or 11, where the gate finger (23) is arranged overlapping the peripheral electrode portion (21B) as viewed in the thickness direction (z-direction) of the insulation film (38, 39).

### [Clause 13]

The semiconductor device according to any one of clauses 1 to 12, where:
the semiconductor device (10) is an insulated gate bipolar transistor (IGBT); and
the drive electrode (21) is an emitter electrode.

[Clause 14]

The semiconductor device according to any one of clauses 1 to 12, where:
the semiconductor device (10) is a trench-gate type metal-oxide-semiconductor field-effect transistor (MOSFET); and
the drive electrode (21) is a source electrode.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A semiconductor device, comprising:
a cell region in which cells are arranged;
a peripheral region surrounding the cell region;
a gate electrode located in the peripheral region; and
a drive electrode including an electrode portion arranged in the cell region, a peripheral electrode portion formed in the peripheral region and distanced from the electrode portion, and a connecting portion connecting the electrode portion and the peripheral electrode portion, wherein:
the peripheral region includes
a well region that is a semiconductor region arranged surrounding the cell region,
an insulation film covering the well region and arranged surrounding the cell region in plan view, and
a gate finger embedded in the insulation film, connected to the gate electrode, and formed surrounding the cell region;
the connecting portion is formed on the insulation film so as to extend across the gate finger; and
the peripheral electrode portion is electrically connected to the well region.

2. The semiconductor device according to claim 1, wherein:
the well region has the form of a loop with a width and includes a peripheral portion that is farther from the electrode portion than a widthwise direction center of the well region;
the peripheral electrode portion includes a contact that is in contact with the well region; and
the contact is in contact with the peripheral portion of the well region as viewed in a thickness direction of the insulation film.

3. The semiconductor device according to claim 2, wherein the contact includes a part located at a side of the gate electrode opposite the electrode portion.

4. The semiconductor device according to claim 3, wherein the contact has the form of a loop at a peripheral end of the peripheral electrode as viewed in a thickness direction of the insulation film.

5. The semiconductor device according to claim 2, wherein:
the gate electrode is arranged overlapping a peripheral end of the peripheral electrode portion; and
the contact has the form of an open loop extending along the peripheral end of the peripheral electrode except for a part where the gate electrode is arranged.

6. The semiconductor device according to claim 2, wherein:
the contact is a first contact; and
the connecting portion includes a second contact that is in contact with the well region located closer to the electrode portion than the gate finger.

7. The semiconductor device according to claim 1, wherein the gate finger is formed by a metal interconnection.

8. The semiconductor device according to claim 7, wherein the gate finger is formed by a material containing tungsten.

9. The semiconductor device according to claim 1, wherein the gate finger is one of a multiple gate fingers arranged in the insulation film and spaced apart from each other in a direction orthogonal to a thickness direction of the insulation film.

10. The semiconductor device according to claim 1, wherein:
the insulation film includes a head surface and a back surface at opposite sides in a thickness direction of the insulation film; and
the gate finger is arranged spaced apart from both of the head surface and the back surface in the thickness direction of the insulation film.

11. The semiconductor device according to claim 10, wherein:
the insulation film includes
a first insulation film that covers the well region and includes the back surface, and
a second insulation film that is formed on the first insulation film and includes the head surface; and
the gate finger is formed on the first insulation film and covered by the second insulation film.

12. The semiconductor device according to claim 10, wherein the gate finger is arranged overlapping the peripheral electrode portion as viewed in the thickness direction of the insulation film.

13. The semiconductor device according to claim 1, wherein:
the semiconductor device is an insulated gate bipolar transistor (IGBT); and
the drive electrode is an emitter electrode.

14. The semiconductor device according to claim 1, wherein:
the semiconductor device is a trench-gate type metal-oxide-semiconductor field-effect transistor (MOSFET); and
the drive electrode is a source electrode.
